(19) United States
(12) Patent Application Publication
(10) Pub. No.: US 2026/0164633 A1
(43) Pub. Date: Jun. 11, 2026

(54) SEMICONDUCTOR DEVICE HAVING HIGH PERFORMANCE

(71) Applicant: TAIWAN SEMICONDUCTOR MANUFACTURING COMPANY, LTD., Hsinchu (TW)

(72) Inventor: Jhon Jhy LIAW, Hsinchu (TW)

(73) Assignee: TAIWAN SEMICONDUCTOR MANUFACTURING COMPANY, LTD., Hsinchu (TW)

(21) Appl. No.: 18/975,922

(22) Filed: Dec. 10, 2024

(51) Int. Cl. H10B 10/00; H01L 23/00; H01L 23/528

(52) U.S. Cl. CPC H10B 10/125; H10W 20/435; H10W 72/242; H10W 72/9415

(57) ABSTRACT

A semiconductor device includes multiple semiconductor cells (SCs). For each SC: multiple transistors are located in a transistor layer (TL); two bit line segments are located in a first front conductive layer (FCL) stacked on the TL, and extend along a first direction; a word line segment is located in a second FCL stacked on the first FCL, and extends along a second direction; and two VSS line segments are located in a back conductive layer stacked on and disposed below the TL, and extend along the first direction. For first and second SCs that are adjacent in the second direction, a source/drain region of a transistor of the first SC and a source/drain region of a transistor of the second SC are electrically connected through a contact located in an upper portion of the TL and extending from the first SC to the second SC along the second direction.

### BACKGROUND

The semiconductor integrated circuit (IC) industry has, over the decades, experienced tremendous advancements and is still undergoing vigorous development. With dramatic advances in technology, the industry pays much attention to the development of semiconductor devices with high performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram illustrating a semiconductor device in accordance with some embodiments.

FIG. 2 is a circuit diagram illustrating a semiconductor cell in accordance with some embodiments.

FIGS. 3 and 4 are schematic diagrams illustrating relative positions (in an X direction and a Y direction) of various components of a semiconductor device in accordance with some embodiments.

FIGS. 5 to 10 are schematic sectional views of the semiconductor device respectively taken along lines C1-C1, C2-C2, C3-C3, C4-C4, C5-C5 and C6-C6 of FIGS. 3 and 4 in accordance with some embodiments.

FIG. 11 is a schematic diagram illustrating relative positions (in an X direction and a Y direction) of various components of a semiconductor device in accordance with some embodiments.

FIG. 12 is a schematic diagram illustrating relative positions (in an X direction and a Y direction) of various components of a semiconductor device in accordance with some embodiments.

FIG. 13 is a schematic diagram illustrating relative positions (in an X direction and a Y direction) of various components of a semiconductor device in accordance with some embodiments.

FIG. 14 is a schematic sectional view of a semiconductor device in accordance with some embodiments.

FIG. 15 is a top view of a bump pad layer in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

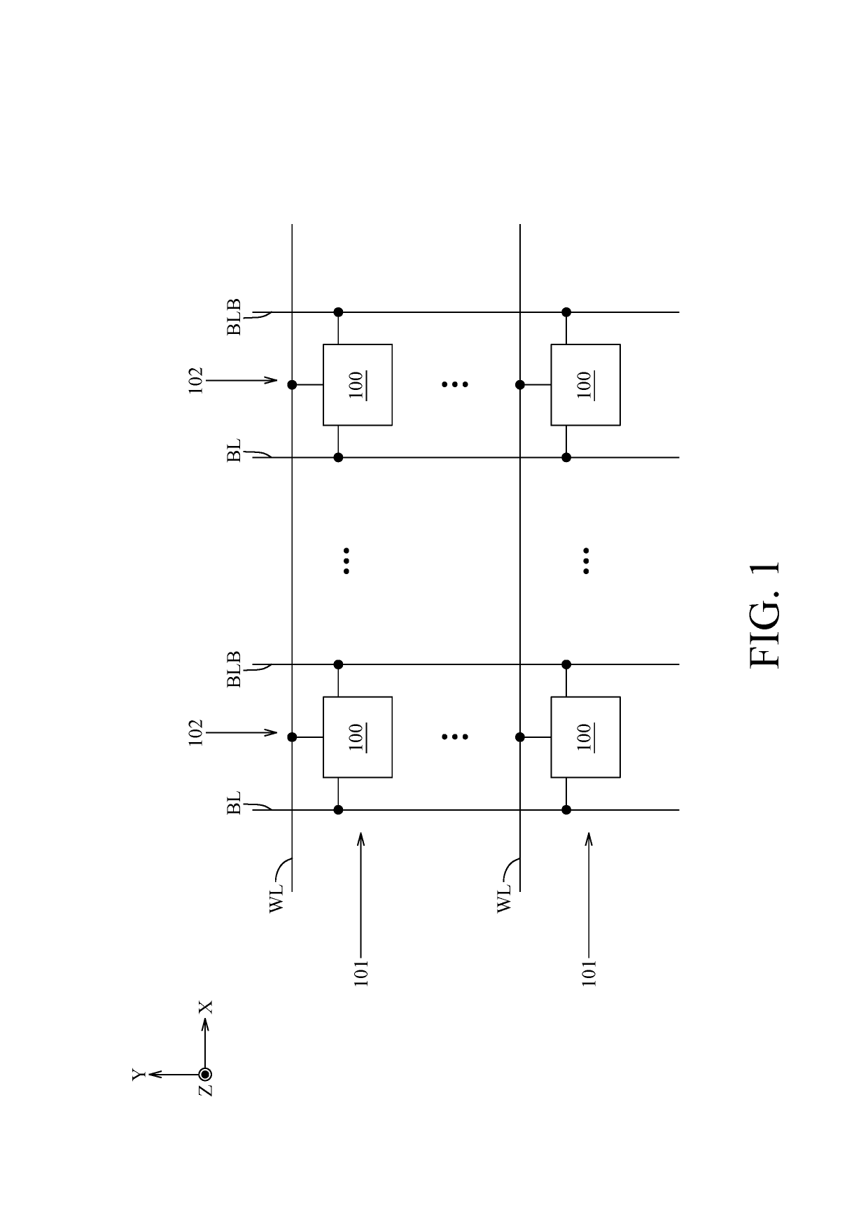

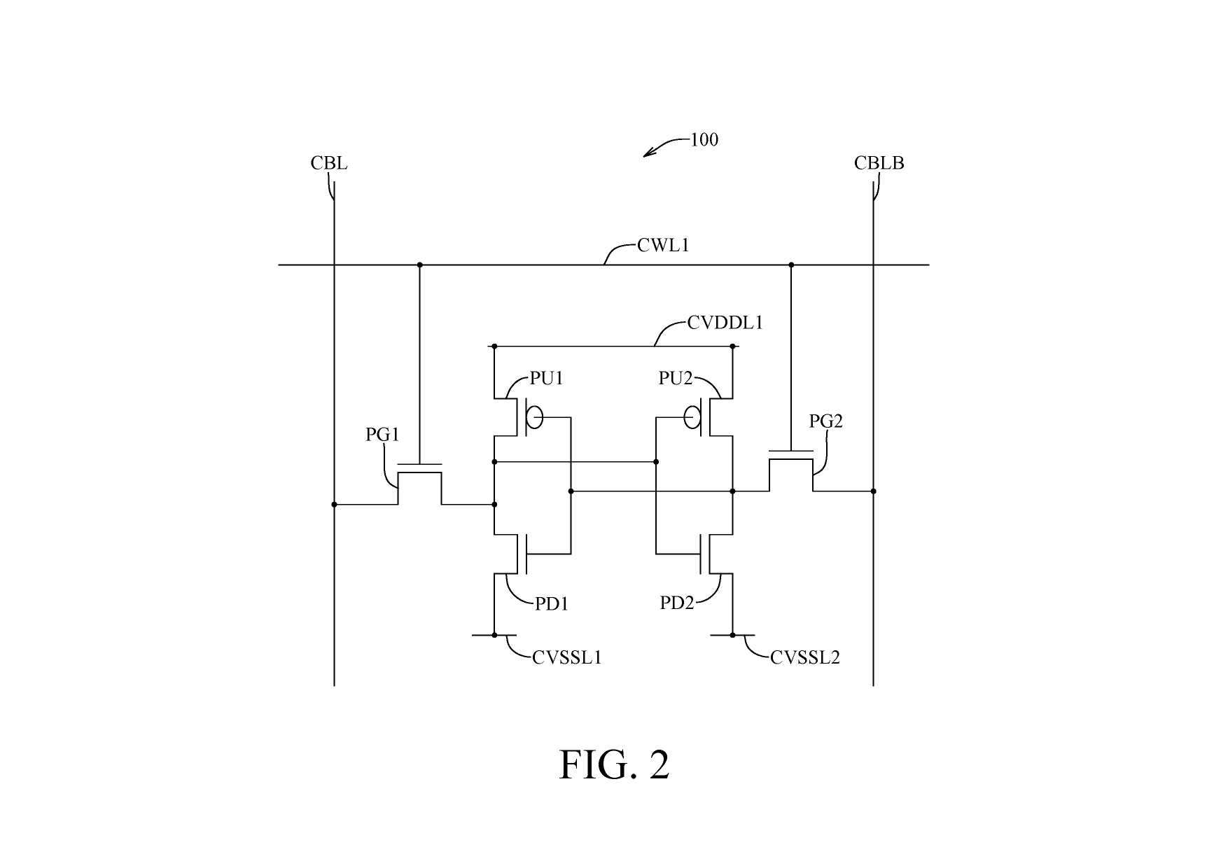

FIG. 1 is a block diagram illustrating a semiconductor device in accordance with some embodiments. FIG. 2 is a circuit diagram illustrating a semiconductor cell in accordance with some embodiments. Referring to FIGS. 1 and 2, the semiconductor device includes a plurality of semiconductor cells 100. The semiconductor cells 100 are arranged in a matrix that has a plurality of rows 101 aligned in a first direction (e.g., a Y direction transverse to a Z direction, where the Z direction points from bottom to top of the semiconductor device) and a plurality of columns 102 aligned in a second direction (e.g., an X direction transverse to the Y direction and the Z direction).

Each of the semiconductor cells 100 is a static random access memory (SRAM) cell, and includes a first pull-up transistor (PU1), a second pull-up transistor (PU2), a first pull-down transistor (PD1), a second pull-down transistor (PD2), a first pass-gate transistor (PG1), a second pass-gate transistor (PG2), a non-inverting bit line segment (CBL), an inverting bit line segment (CBLB), a word line segment (CWL1), a VDD line segment (CVDDL1), a first VSS line segment (CVSSL1), a second VSS line segment (CVSSL2) and a third VSS line segment (not shown). Each of the first pull-up transistor (PU1), the second pull-up transistor (PU2), the first pull-down transistor (PD1), the second pull-down transistor (PD2), the first pass-gate transistor (PG1) and the second pass-gate transistor (PG2) includes a gate electrode, a first source/drain region and a second source/drain region. The first source/drain region of the first pull-up transistor (PU1), the first source/drain region of the first pull-down transistor (PD1), the first source/drain region of the first pass-gate transistor (PG1), the gate electrode of the second pull-up transistor (PU2) and the gate electrode of the second pull-down transistor (PD2) are electrically connected to each other. The first source/drain region of the second pull-up transistor (PU2), the first source/drain region of the second pull-down transistor (PD2), the first source/drain region of the second pass-gate transistor (PG2), the gate electrode of the first pull-up transistor (PU1) and the gate electrode of the first pull-down transistor (PD1) are electrically connected to each other. The second source/drain region of the first pull-up transistor (PU1) and the second source/drain region of the second pull-up transistor (PU2) are electrically connected to the VDD line segment (CVDDL1). The second source/drain region of the first pull-down transistor (PD1) is electrically connected to the first VSS line segment (CVSSL1). The second source/drain region of the second pull-down transistor (PD2) is electrically connected to the second VSS line segment (CVSSL2). The gate electrode of the first pass-gate transistor (PG1) and the gate electrode of the second pass-gate transistor (PG2) are electrically connected to the word line segment (CWL1). The second source/drain region of the first pass-gate transistor (PG1) is electrically connected to the non-inverting bit line segment (CBL). The second source/drain region of the second pass-gate transistor (PG2) is electrically connected to the inverting bit line segment (CBLB). The third VSS line segment is electrically connected to the first VSS line segment (CVSSL1) and the second VSS line segment (CVSSL2). Therefore, the first pull-up transistor (PU1) and the first pull-down transistor (PD1) cooperatively form a first inverter. The second pull-up transistor (PU2) and the second pull-down transistor (PD2) cooperatively form a second inverter. The first inverter and the second inverter are cross-coupled so as to form a data latch for storing data. When the first pass-gate transistor (PG1) and the second pass-gate transistor (PG2) conduct, a write operation and a read operation are allowed to be performed on the data latch.

With respect to each of the rows 101, the word line segments (CWL1) of the semiconductor cells 100 in the row 101 are connected in series so as to form a word line (WL) that corresponds to the row 101 and that extends in the X direction. With respect to each of the columns 102, the non-inverting bit line segments (CBL) of the semiconductor cells 100 in the column 102 are connected in series so as to form a non-inverting bit line (BL) that corresponds to the column 102 and that extends in the Y direction, and the inverting bit line segments (CBLB) of the semiconductor cells 100 in the column 102 are connected in series so as to form an inverting bit line (BLB) that corresponds to the column 102 and that extends in the Y direction.

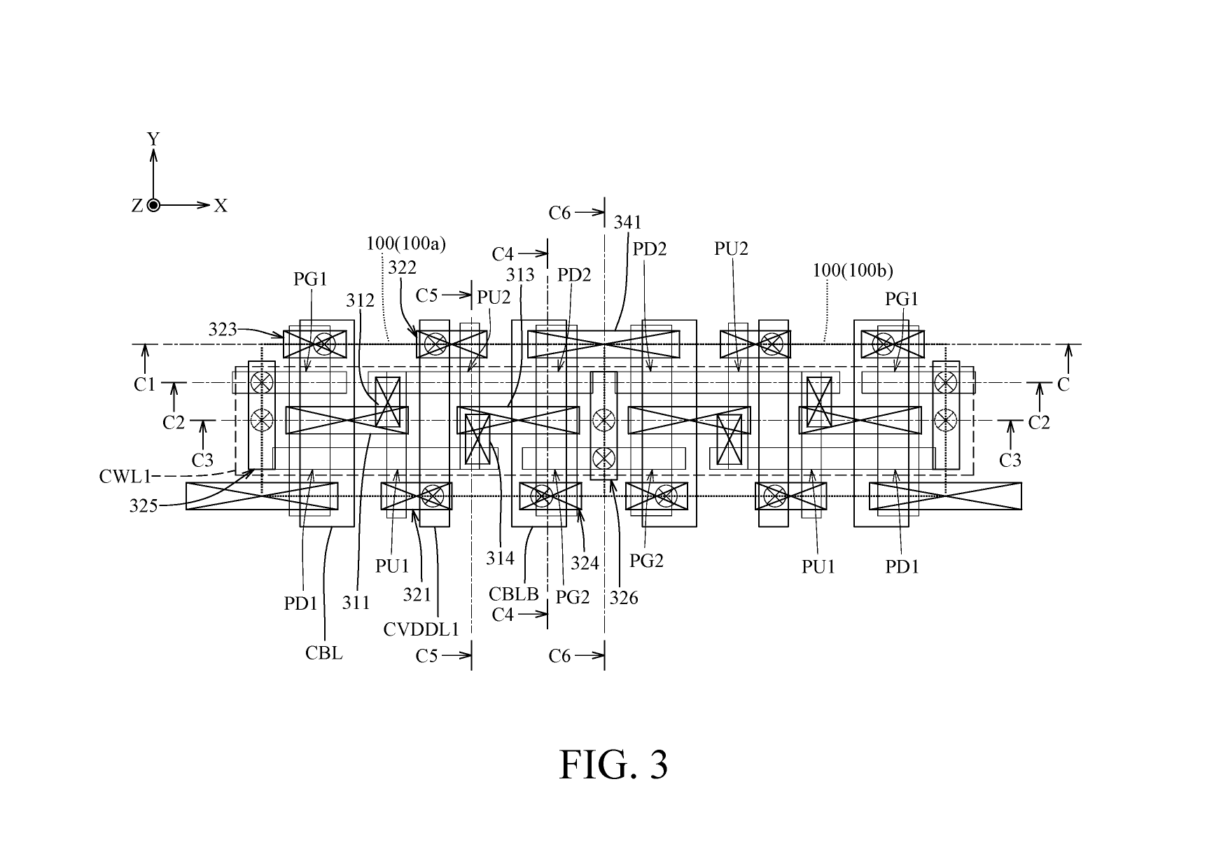

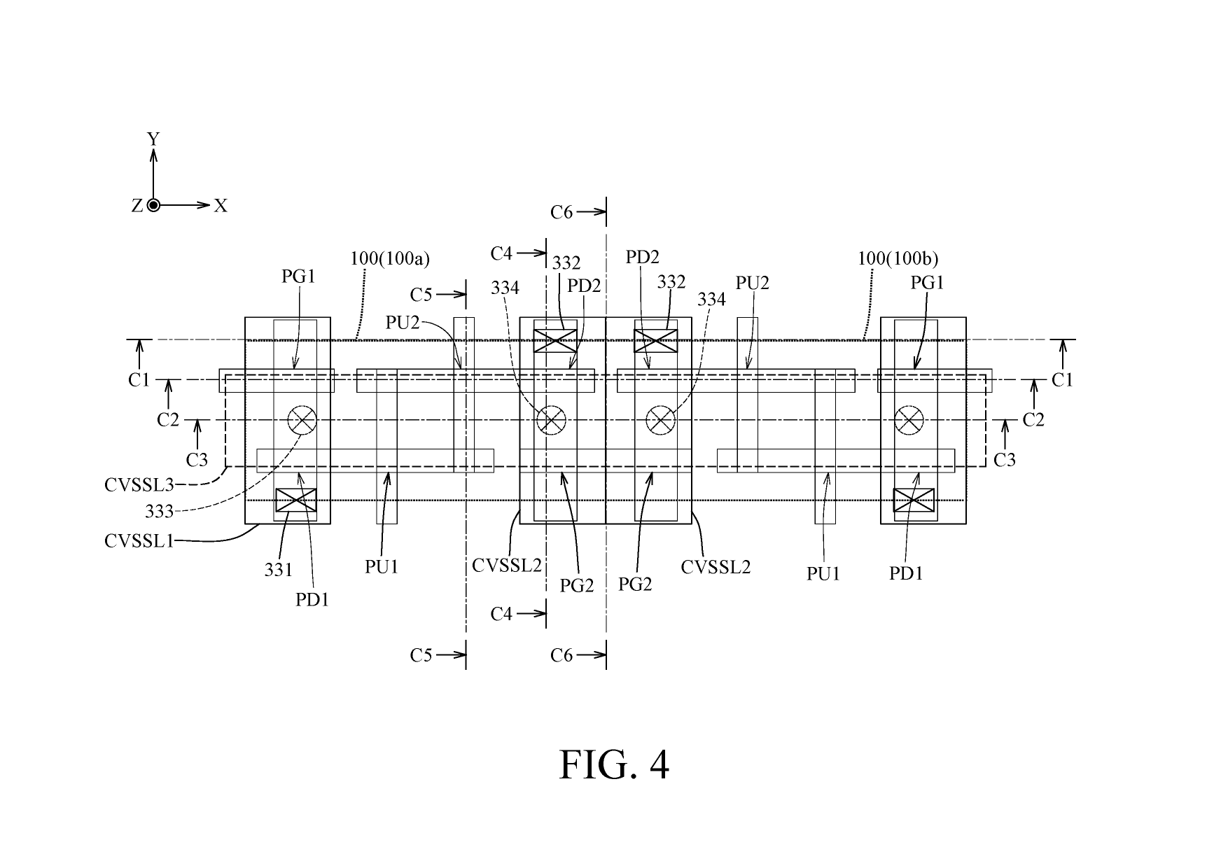

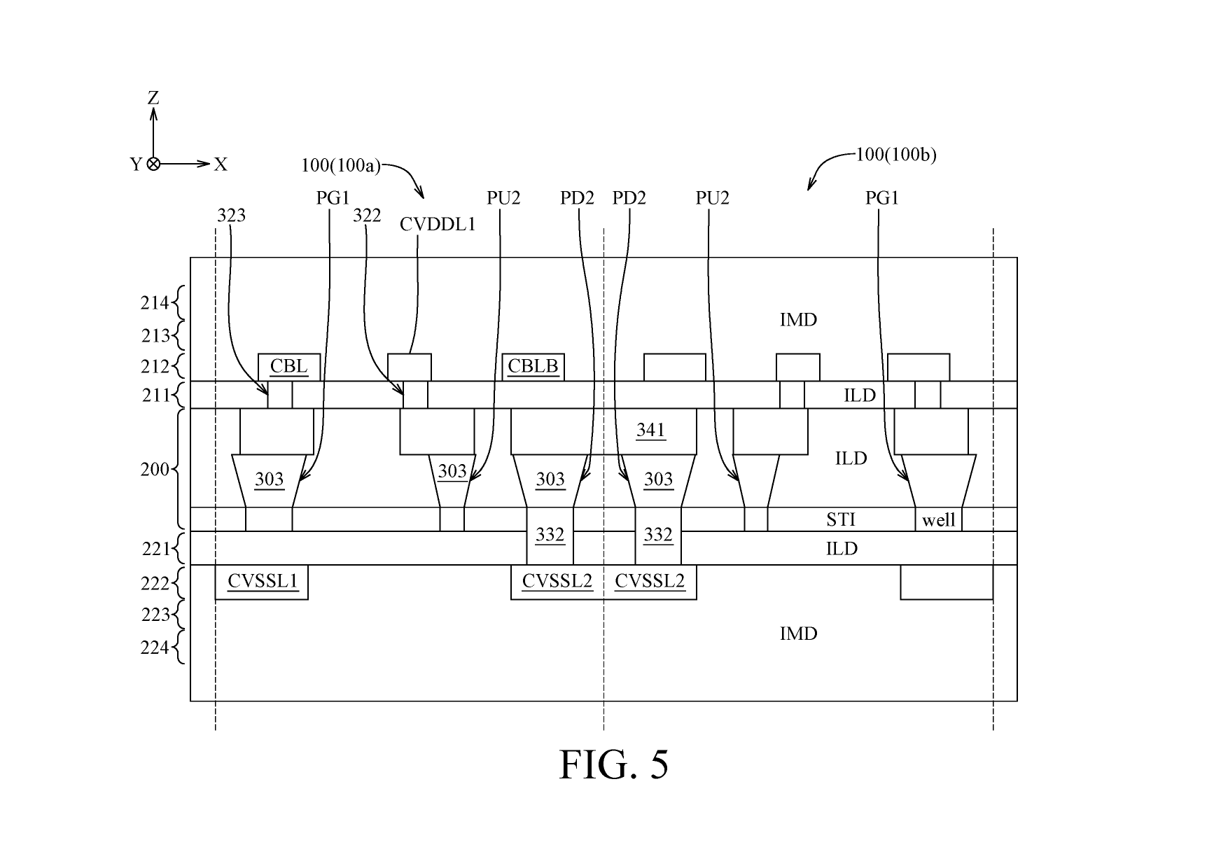

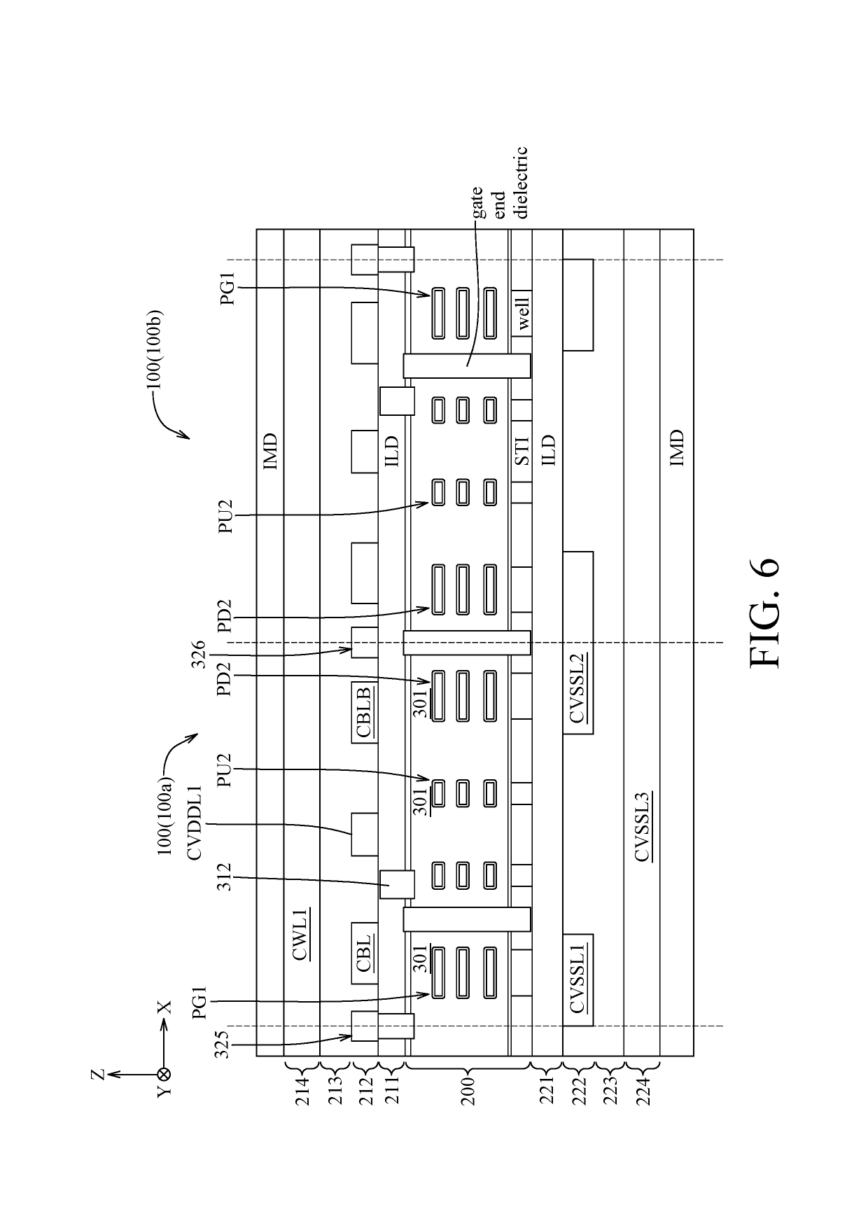

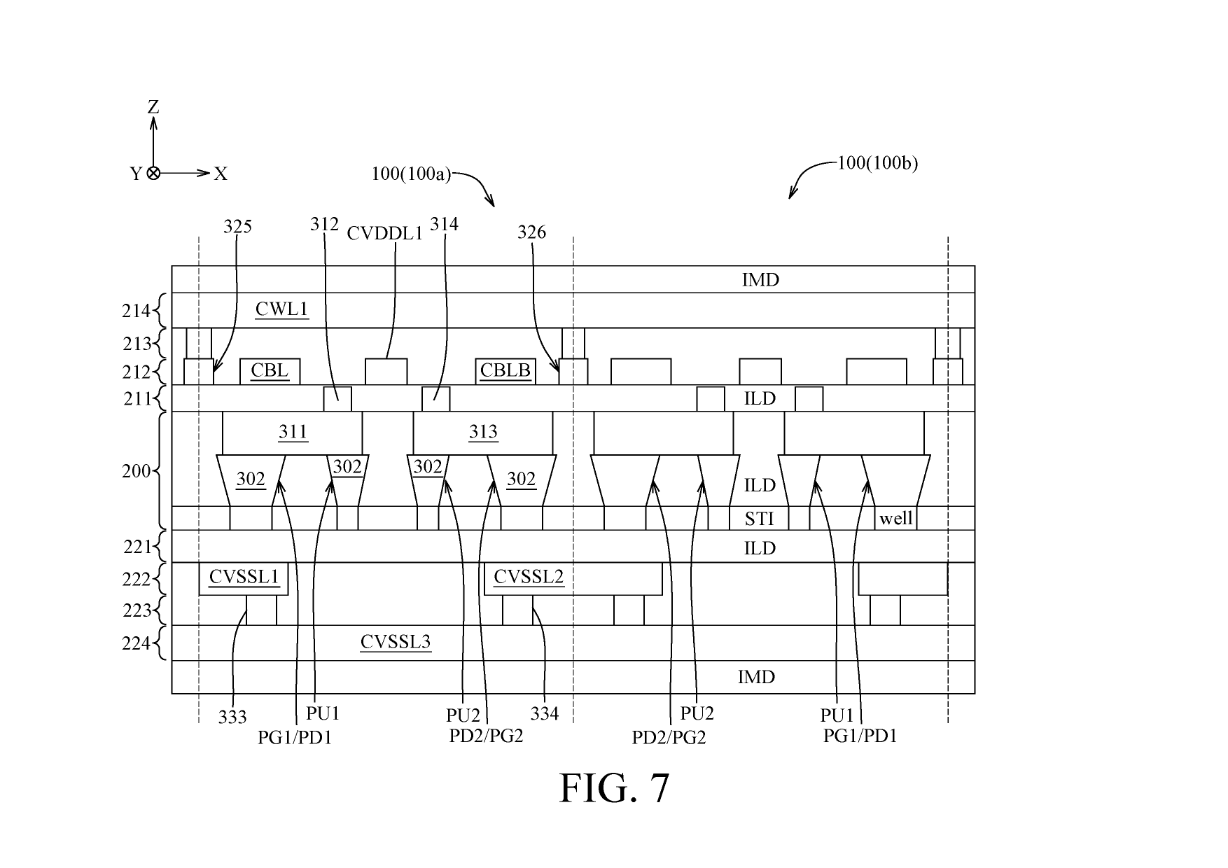

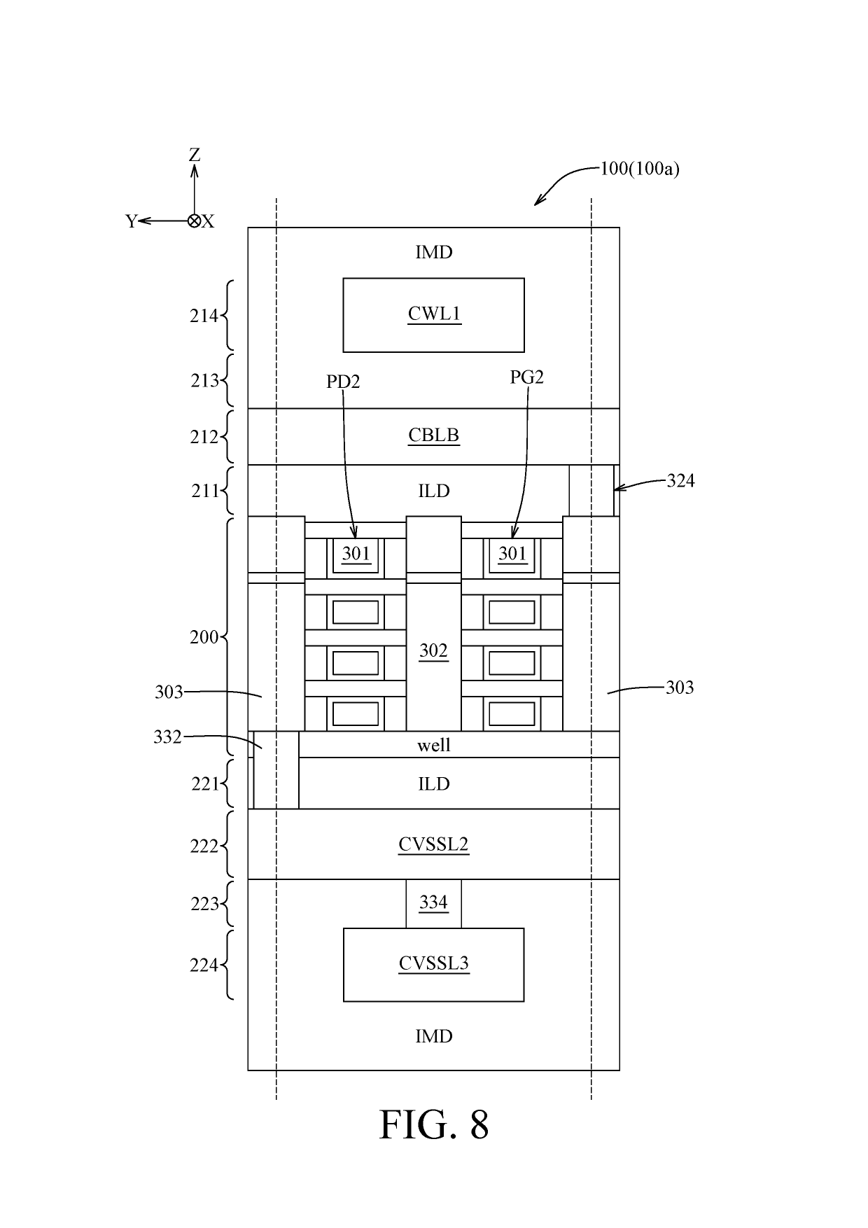

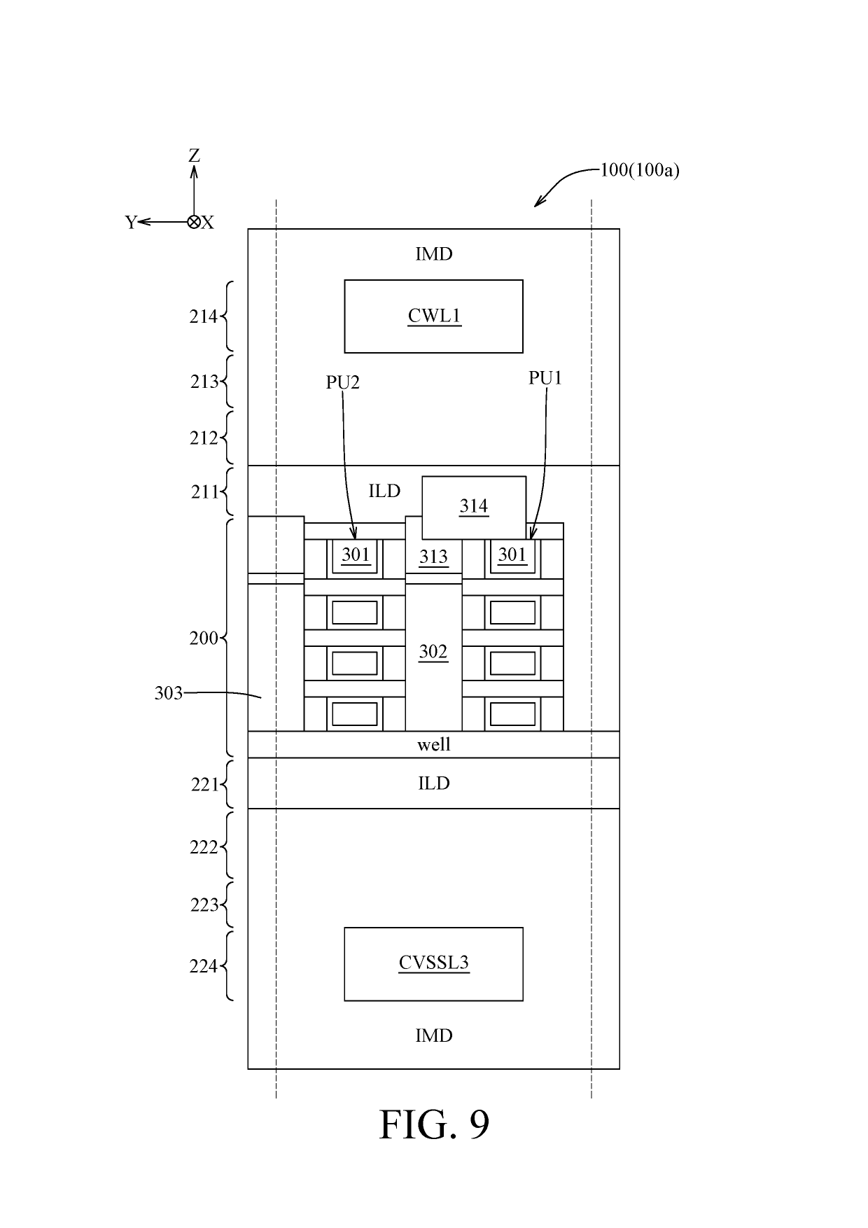

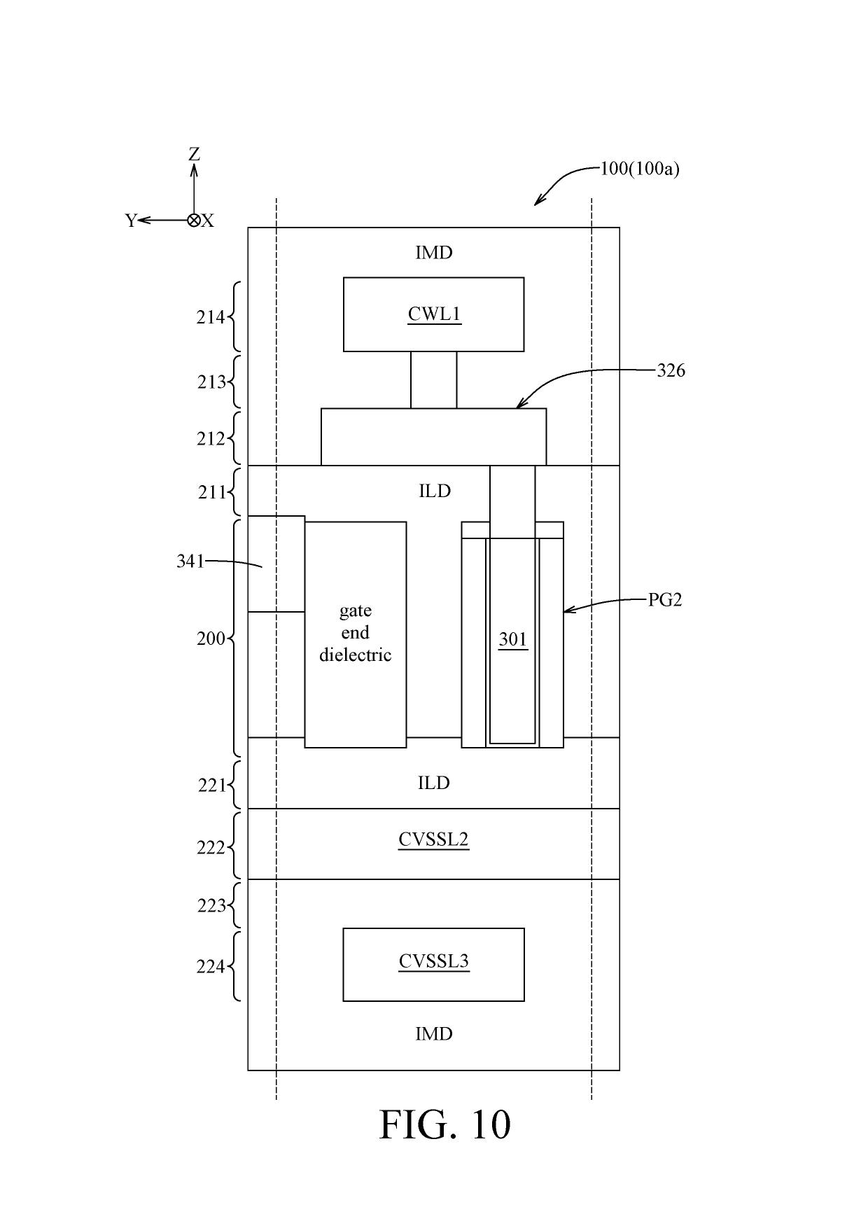

FIGS. 3 and 4 are schematic diagrams illustrating relative positions (in the X direction and the Y direction) of various components of a semiconductor device in accordance with some embodiments. FIGS. 5 to 10 are schematic sectional views of the semiconductor device respectively taken along lines C1-C1, C2-C2, C3-C3, C4-C4, C5-C5 and C6-C6 of FIGS. 3 and 4 in accordance with some embodiments. It should be noted that: only two of semiconductor cells 100 of the semiconductor device that are adjacent to each other in the X direction are depicted in FIGS. 3 and 4; and each of FIGS. 3 and 4 omits the depiction of some components of the two semiconductor cells 100 for the sake of clarity.

Referring to FIGS. 3 to 10, with respect to each of the semiconductor cells 100, the first pull-up transistor (PU1), the second pull-up transistor (PU2), the first pull-down transistor (PD1), the second pull-down transistor (PD2), the first pass-gate transistor (PG1) and the second pass-gate transistor (PG2) are located in a transistor layer 200. The non-inverting bit line segment (CBL), the inverting bit line segment (CBLB) and the VDD line segment (CVDDL1) are located in a first front metal layer (i.e., a first front conductive layer) 212 stacked on the transistor layer 200, and each extend along the Y direction. The VDD line segment (CVDDL1) is disposed between the non-inverting bit line segment (CBL) and the inverting bit line segment (CBLB). The word line segment (CWL1) is located in a second front metal layer (i.e., a second front conductive layer) 214 stacked on the first front metal layer 212, and extends along the X direction. The first VSS line segment (CVSSL1) and the second VSS line segment (CVSSL2) are located in a first back metal layer (i.e., a first back conductive layer) 222 stacked below the transistor layer 200, and each extend along the Y direction. The third VSS line segment (CVSSL3) is located in a second back metal layer (i.e., a second back conductive layer) 224 stacked below the first back metal layer 222, and extends along the X direction. The gate electrode of each of the first pull-up transistor (PU1), the second pull-up transistor (PU2), the first pull-down transistor (PD1), the second pull-down transistor (PD2), the first pass-gate transistor (PG1) and the second pass-gate transistor (PG2) extends in the X direction. The first source/drain region 302 of the first pass-gate transistor (PG1) and the first source/drain region 302 of the first pull-down transistor (PD1) share the same region (i.e., the first pass-gate transistor (PG1) and the first pull-down transistor (PD1) have a common first source/drain region 302). The common first source/drain region 302 of the first pass-gate transistor (PG1) and the first pull-down transistor (PD1) is connected to the first source/drain region 302 of the first pull-up transistor (PU1) through a front contact 311 that is located in an upper portion of the transistor layer 200. The front contact 311 is connected to the gate electrode 301 of the second pull-up transistor (PU2) through a front contact 312 that is located in a bottom front via layer 211 disposed between the first front metal 212 and the transistor layer 200. The gate electrode 301 of the second pull-up transistor (PU2) and the gate electrode 301 of the second pull-down transistor (PD2) are in contact with each other. Accordingly, the electrical connection among the first source/drain region 302 of the first pass-gate transistor (PG1), the first source/drain region 302 of the first pull-down transistor (PD1), the first source/drain region 302 of the first pull-up transistor (PU1), the gate electrode 301 of the second pull-up transistor (PU2) and the gate electrode 301 of the second pull-down transistor (PD2) is established. The first source/drain region 302 of the second pass-gate transistor (PG2) and the first source/drain region 302 of the second pull-down transistor (PD2) share the same region (i.e., the second pass-gate transistor (PG2) and the second pull-down transistor (PD2) have a common first source/drain region 302). The common first source/drain region 302 of the second pass-gate transistor (PG2) and the second pull-down transistor (PD2) is connected to the first source/drain region 302 of the second pull-up transistor (PU2) through a front contact 313 that is located in the upper portion of the transistor layer 200. The front contact 313 is connected to the gate electrode of the first pull-up transistor (PU1) through a front contact 314 that is located in the bottom front via layer 211. The gate electrode of the first pull-up transistor (PU1) and the gate electrode of the first pull-down transistor (PD1) are in contact with each other. Accordingly, the electrical connection among the first source/drain region 302 of the second pass-gate transistor (PG2), the first source/drain region 302 of the second pull-down transistor (PD2), the first source/drain region 302 of the second pull-up transistor (PU2), the gate electrode of the first pull-up transistor (PU1) and the gate electrode of the first pull-down transistor (PD1) is established. The second source/drain region of the first pull-up transistor (PU1) is electrically connected to the VDD line segment (CVDDL1) through an interconnect element 321 that includes a front contact located in the upper portion of the transistor layer 200 and a front via located in the bottom front via layer 211. The second source/drain region 303 of the second pull-up transistor (PU2) is electrically connected to the VDD line segment (CVDDL1) through an interconnect element 322 that includes a front contact located in the upper portion of the transistor layer 200 and a front via located in the bottom front via layer 211. The second source/drain region 303 of the first pass-gate transistor (PG1) is electrically connected to the non-inverting bit line segment (CBL) through an interconnect element 323 that includes a front contact located in the upper portion of the transistor layer 200 and a front via located in the bottom front via layer 211. The second source/drain region of the second pass-gate transistor (PG2) is electrically connected to the inverting bit line segment (CBLB) through an interconnect element 324 that includes a front contact located in the upper portion of the transistor layer 200 and a front via located in the bottom front via layer 211. The gate electrode 301 of the first pass-gate transistor (PG1) is electrically connected to the word line segment (CWL1) through an interconnect element 325 that includes a front via located in the bottom front via layer 211, a front landing pad located in the first front metal layer 212, and another front via located in a first front via layer 213 disposed between the second front metal layer 214 and the first front metal layer 212. The gate electrode of the second pass-gate transistor (PG2) is electrically connected to the word line segment (CWL1) through an interconnect element 326 that includes a front via located in the bottom front via layer 211, a front landing pad located in the first front metal layer 212, and another front via located in the first front via layer 213. The second source/drain region of the first pull-down transistor (PD1) is electrically connected to the first VSS line segment (CVSSL1) through a back contact 331 that is located in a lower portion of the transistor layer 200 and in a top back via layer 221 disposed between the transistor layer 200 and the first back metal layer 222. The second source/drain region 303 of the second pull-down transistor (PD2) is electrically connected to the second VSS line segment (CVSSL2) through a back contact 332 that is located in the lower portion of the transistor layer 200 and the top back via layer 221. The third VSS line segment (CVSSL3) is electrically connected to the first VSS line segment (CVSSL1) through a back via 333 that is located in a first back via layer 223 disposed between the first back metal layer 222 and the second back metal layer 224, and is electrically connected to the second VSS line segment (CVSSL2) through a back via 334 that is located in the first back via layer 223.

In some embodiments, each of the transistors (PU1, PU2, PD1, PD2, PG1, PG2) of each of the semiconductor cells 100 may be a planar field effect transistor (planar FET), a three-dimensional field effect transistor (3D FET) such as a fin field effect transistor (FinFET), a nanosheet gate-all-around field effect transistor (GAAFET), a nanowire GAAFET, a forksheet field effect transistor, a complementary field effect transistor (CFET), or other suitable FETs. FIGS. 5 to 10 depict an example where each of the transistors (PU1, PU2, PD1, PD2, PG1, PG2) of each of the semiconductor cells 100 is a nanosheet GAAFET.

Referring to FIGS. 1 to 4, with respect to each of the rows 101: the word line segments (CWL1) of any two adjacent ones of the semiconductor cells 100 in the row 101 are in contact with each other, so the word line segments (CWL1) of the semiconductor cells 100 in the row 101 cooperatively form the word line (WL) that corresponds to the row 101; and the third VSS line segments (CVSSL3) of any two adjacent ones of the semiconductor cells 100 in the row 101 are in contact with each other, so the third VSS line segments (CVSSL3) of the semiconductor cells 100 in the row 101 cooperatively form a third VSS line that corresponds to the row 101.

With respect to each of the columns 102: the non-inverting bit line segments (CBL) of any two adjacent ones of the semiconductor cells 100 in the column 102 are in contact with each other, so the non-inverting bit line segments (CBL) of the semiconductor cells 100 in the column 102 cooperatively form the non-inverting bit line (BL) that corresponds to the column 102; the inverting bit line segments (CBLB) of any two adjacent ones of the semiconductor cells 100 in the column 102 are in contact with each other, so the inverting bit line segments (CBLB) of the semiconductor cells 100 in the column 102 cooperatively form the inverting bit line (BLB) that corresponds to the column 102; the VDD line segments (CVDDL1) of any two adjacent ones of the semiconductor cells 100 in the column 102 are in contact with each other, so the VDD line segments (CVDDL1) of the semiconductor cells 100 in the column 102 cooperatively form a VDD line that corresponds to the column 102 and that is for transmitting a first supply voltage; the first VSS line segments (CVSSL1) of any two adjacent ones of the semiconductor cells 100 in the column 102 are in contact with each other, so the first VSS line segments (CVSSL1) of the semiconductor cells 100 in the column 102 cooperatively form a first VSS line that corresponds to the column 102 and that is for transmitting a second supply voltage lower than the first supply voltage in magnitude; and the second VSS line segments (CVSSL2) of any two adjacent ones of the semiconductor cells 100 in the column 102 are in contact with each other, so the second VSS line segments (CVSSL2) of the semiconductor cells 100 in the column 102 cooperatively form a second VSS line that corresponds to the column 102 and that is for transmitting the second supply voltage.

By virtue of the third VSS lines electrically connecting the first VSS lines and the second VSS lines in parallel, a line resistance (in the Y direction) of a combination of the first VSS lines and the second VSS lines can be reduced, thereby reducing a voltage drop caused by the combination of the first VSS lines and the second VSS lines, reducing power consumption of the semiconductor device, and increasing a maximum operating speed of the semiconductor device.

Referring to FIGS. 1 to 5, with respect to any two of the semiconductor cells 100 that are adjacent to each other in the X direction (one of which is also referred to as a first semiconductor cell (100a) hereinafter, and the other one of which is also referred to as a second semiconductor cell (100b) hereinafter), the first semiconductor cell (100a) and the second semiconductor cell (100b) are mirror symmetric with each other about a plane transverse to the X direction, and the second source/drain region of the first or second pull-down transistor (PD1/PD2) of the first semiconductor cell (100a) and the second source/drain region of the first or second pull-down transistor (PD1/PD2) of the second semiconductor cell (100b) that are adjacent to each other (e.g., the second source/drain region 303 of the second pull-down transistor (PD2) of the first semiconductor cell (100a) and the second source/drain region 303 of the second pull-down transistor (PD2) of the second semiconductor cell (100b) as depicted in FIGS. 3 and 5) are electrically connected to each other through a front contact 341 that is located in the upper portion of the transistor layer 200 and that extends from a cell region of the first semiconductor cell (100a) to a cell region of the second semiconductor cell (100b) along the X direction, so as to reduce a line resistance (in the Y direction) of a combination of the first or second VSS line segment (CVSSL1/CVSSL2) of the first semiconductor cell (100a) and the first or second VSS line segment (CVSSL1/CVSSL2) of the second semiconductor cell (100b) that are adjacent to each other (e.g., the second VSS line segment (CVSSL2) of the first semiconductor cell (100a) and the second VSS line segment (CVSSL2) of the second semiconductor cell (100b) as depicted in FIGS. 3 and 5). Therefore, the line resistance (in the Y direction) of the combination of the first VSS lines and the second VSS lines can be reduced, thereby reducing the voltage drop caused by the combination of the first VSS lines and the second VSS lines, reducing the power consumption of the semiconductor device, and increasing the maximum operating speed of the semiconductor device. In addition, the semiconductor device can still work even if the back contact 332 of one of the first semiconductor cell (100a) and the second semiconductor cell (100b) has failed, so yield of the semiconductor device can be enhanced. In some embodiments, the first or second VSS line segment (CVSSL1/CVSSL2) of the first semiconductor cell (100a) and the first or second VSS line segment (CVSSL1/CVSSL2) of the second semiconductor cell (100b) that are adjacent to each other (e.g., the second VSS line segment (CVSSL2) of the first semiconductor cell (100a) and the second VSS line segment (CVSSL2) of the second semiconductor cell (100b) as depicted in FIGS. 3 and 5) may be in contact with each other, so as to further reduce the line resistance (in the Y direction) of the combination of the first or second VSS line segment (CVSSL1/CVSSL2) of the first semiconductor cell (100a) and the first or second VSS line segment (CVSSL1/CVSSL2) of the second semiconductor cell (100b) that are adjacent to each other.

In the cell region of each of the semiconductor cells 100, the first front metal layer 212 is free of the first VSS line segment (CVSSL1) and the second VSS line segment (CVSSL2). This can facilitate shrinking of the semiconductor device. In addition, the first front metal layer 212 can have more space for the non-inverting bit line segment (CBL) and the inverting bit line segment (CBLB), and each of the non-inverting bit line segment (CBL) and the inverting bit line segment (CBLB) can be wide so as to have a low line resistance (in the Y direction). Therefore, the non-inverting bit lines (BL) that respectively correspond to the columns 102 and the non-inverting bit lines (BLB) that respectively correspond to the columns 102 can each have a low line resistance (in the Y direction), and can thus cause a low resistance-capacitance (RC) time delay. This is beneficial to increasing the maximum operating speed of the semiconductor device and reducing a minimum write voltage of the semiconductor device.

In the cell region of each of the semiconductor cells 100, since the second front metal layer 214 only includes the word line segment (CWL1), the word line segment (CWL1) can be wide so as to have a low line resistance (in the X direction). Therefore, the word lines (WL) that respectively correspond to the rows 101 can each have a low line resistance (in the X direction), and can thus cause a low RC time delay. This is beneficial to increasing the maximum operating speed of the semiconductor device.

In some embodiments, with respect to each of the semiconductor cells 100, the second source/drain region of the first pull-down transistor (PD1) may be electrically connected to the first VSS line segment (CVSSL1) through not only the back contact 331 but also a back via (not shown) that is located in a top back via layer (not shown) disposed between the back contact layer 221 and the first back metal layer 222. The second source/drain region 303 of the second pull-down transistor (PD2) may be electrically connected to the second VSS line segment (CVSSL2) through not only the back contact 332 but also a back via (not shown) that is located in the top back via layer.

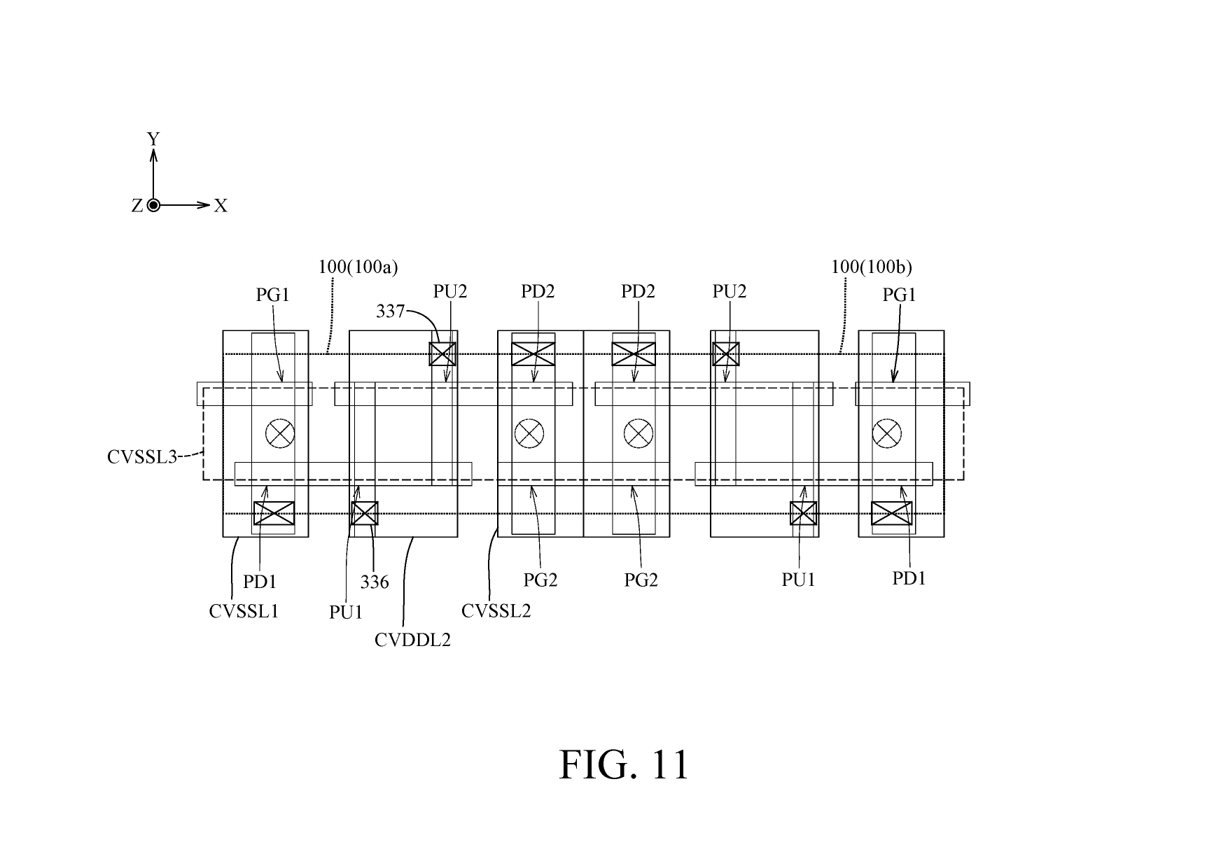

FIG. 11 is a schematic diagram illustrating relative positions (in the X direction and the Y direction) of various components of a semiconductor device in accordance with some embodiments. It should be noted that: only two of semiconductor cells 100 of the semiconductor device that are adjacent to each other in the X direction are depicted in FIG. 11; and FIG. 11 omits the depiction of some components of the two semiconductor cells for the sake of clarity. Referring to FIGS. 1, 3 and 11, the semiconductor device depicted in FIGS. 1, 3 and 11 is similar to the semiconductor device described with reference to FIGS. 1 to 10, but differs therefrom in that each of the semiconductor cells 100 of the semiconductor device depicted in FIGS. 1, 3 and 11 further includes another VDD line segment (CVDDL2). The VDD line segment (CVDDL2) is located in the first back metal layer 222 (see FIG. 5), extends along the Y direction, and is disposed between the first VSS line segment (CVSSL1) and the second VSS line segment (CVSSL2). The VDD line segment (CVDDL2) is electrically connected to the second source/drain region of the first pull-up transistor (PU1) through a back contact 336 located in the lower portion of the transistor layer 200 (see FIG. 5) and the back contact layer 221 (see FIG. 5), and is electrically connected to the second source/drain region of the second pull-up transistor (PU2) through a back contact 337 located in the lower portion of the transistor layer 200 (see FIG. 5) and the back contact layer 221 (see FIG. 5), so the VDD line segment (CVDDL1) and the VDD line segment (CVDDL2) are electrically connected to each other. With respect to each of the columns 102, the VDD line segments (CVDDL2) of any two adjacent ones of the semiconductor cells 100 in the column 102 are in contact with each other, and the VDD line segments (CVDDL2) of the semiconductor cells 100 in the column 102 cooperate with the VDD line segments (CVDDL1) of the semiconductor cells 100 in the column 102 to form the VDD line that corresponds to the column 102. Therefore, the VDD lines that respectively correspond to the columns 102 can each have a low line resistance (in the Y direction), and can thus cause a low voltage drop. This is beneficial to reducing the power consumption of the semiconductor device and increasing the maximum operating speed of the semiconductor device.

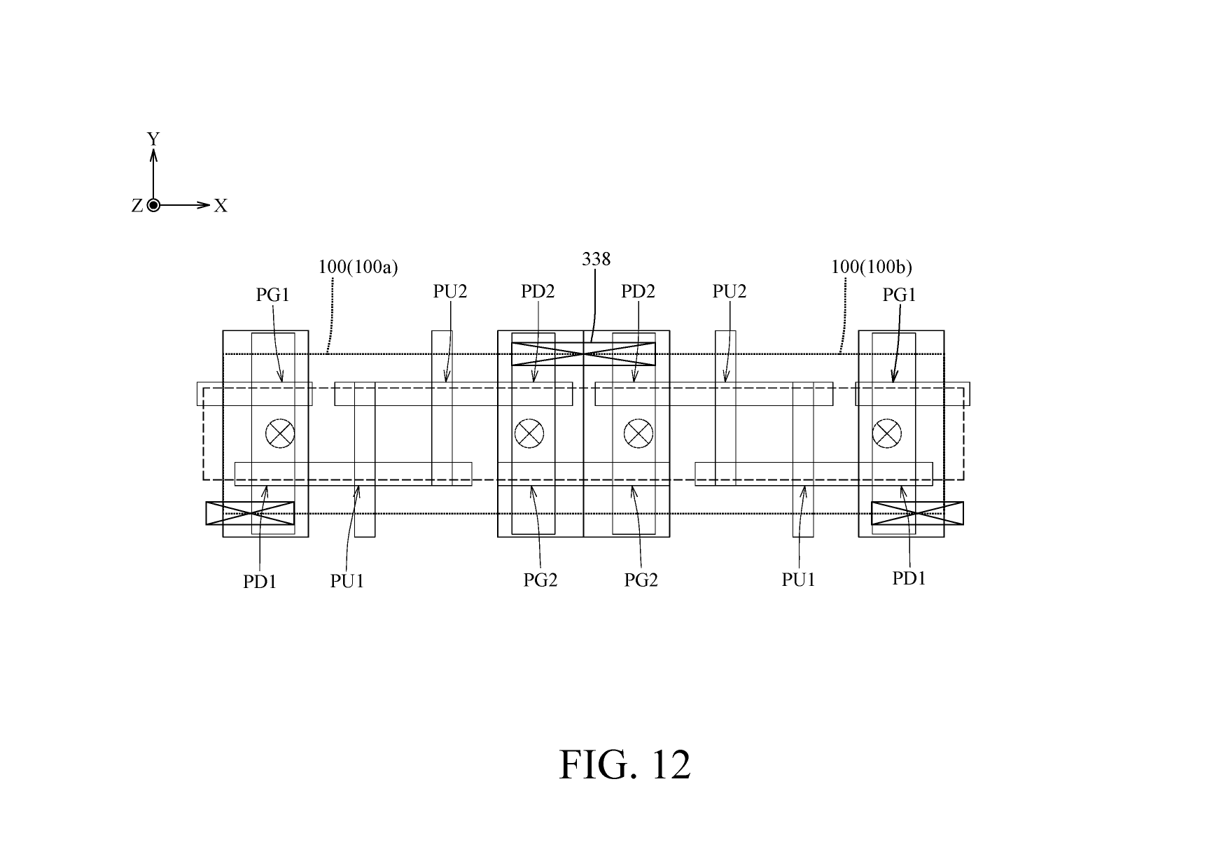

FIG. 12 is a schematic diagram illustrating relative positions (in the X direction and the Y direction) of various components of a semiconductor device in accordance with some embodiments. It should be noted that: only two of semiconductor cells 100 of the semiconductor device that are adjacent to each other in the X direction are depicted in FIG. 12; and FIG. 12 omits the depiction of some components of the two semiconductor cells for the sake of clarity. Referring to FIGS. 1, 3 and 12, the semiconductor device depicted in FIGS. 1, 3 and 12 is similar to the semiconductor device described with reference to FIGS. 1 to 10, but differs therefrom in that the back contact 332 of the first semiconductor cell (100a) and the back contact 332 of the second semiconductor cell (100b) of the semiconductor device described with reference to FIGS. 1 to 10 are replaced by a back contact 338. The back contact 338 is located in the lower portion of the transistor layer 200 (see FIG. 5) and the back contact layer 221 (see FIG. 5), extends from the cell region of the first semiconductor cell (100a) to the cell region of the second semiconductor cell (100b) along the X direction, and establishes electrical connection between the second source/drain region of the second pull-down transistor (PD2) of the first semiconductor cell (100a) and the second source/drain region of the second pull-down transistor (PD2) of the second semiconductor cell (100b). Therefore, the line resistance (in the Y direction) of the combination of the second VSS line segment (CVSSL2) of the first semiconductor cell (100a) and the second VSS line segment (CVSSL2) of the second semiconductor cell (100b) can be reduced. Similarly, with respect to the first semiconductor cell (100a) and a third semiconductor cell 100 that is adjacent to the first semiconductor cell (100a) and opposite to the second semiconductor cell (100b) in the X direction, the back contact 331 of the first semiconductor cell (100a) and the back contact 331 of the third semiconductor cell 100 of the semiconductor device described with reference to FIGS. 1 to 10 may be replaced by a back contact (not shown), which is located in the lower portion of the transistor layer 200 (see FIG. 5) and the back contact layer 221 (see FIG. 5), extends from the cell region of the third semiconductor cell 100 to the cell region of the first semiconductor cell (100a) along the X direction, and establishes electrical connection between the second source/drain region of the first pull-down transistor (PD1) of the first semiconductor cell (100a) and the second source/drain region of the first pull-down transistor (PD1) of the third semiconductor cell 100, so the line resistance (in the Y direction) of the combination of the first VSS line segment (CVSSL1) of the first semiconductor cell (100a) and the first VSS line segment (CVSSL1) of the third semiconductor cell 100 can be reduced. As such, the combination of the first VSS lines and the second VSS lines can have a low line resistance (in the Y direction), and thus can cause a low voltage drop. This is beneficial to reducing the power consumption of the semiconductor device and increasing the maximum operating speed of the semiconductor device.

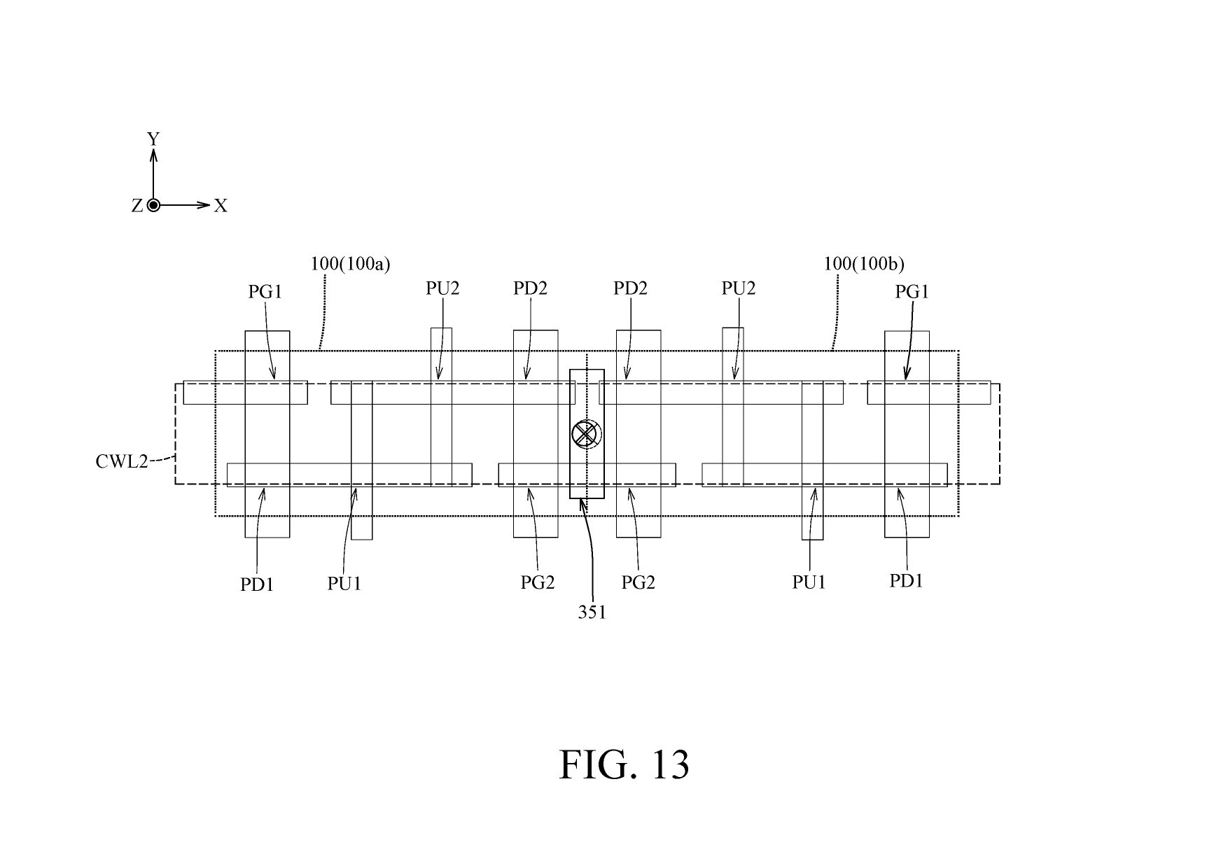

FIG. 13 is a schematic diagram illustrating relative positions (in the X direction and the Y direction) of various components of a semiconductor device in accordance with some embodiments. It should be noted that: only two of the semiconductor cells 100 of the semiconductor device that are adjacent to each other in the X direction are depicted in FIG. 13; and FIG. 13 omits the depiction of some components of the two semiconductor cells 100 for the sake of clarity. Referring to FIGS. 1, 3, 4 and 13, a variation of the semiconductor device is shown, and is similar to the semiconductor device described with reference to FIGS. 1 to 10, but differs therefrom in that each of the semiconductor cells 100 of the variation further includes another word line segment (CWL2). The word line segment (CWL2) is located in an additional front metal layer (i.e., an additional front conductive layer) stacked on the second front metal layer 214 (see FIG. 5), extends along the X direction, and is electrically connected to the word line segment (CWL1). With respect to each of the rows 101, the word line segments (CWL2) of any two adjacent ones of the semiconductor cells 100 in the row 101 are in contact with each other, and the word line segments (CWL2) of the semiconductor cells 100 in the row 101 cooperate with the word line segments (CWL1) of the semiconductor cells 100 in the row 101 to form the word line (WL) that corresponds to the row 101. FIGS. 3, 4 and 13 depict an example where, with respect to each of the semiconductor cells 100, the word line segment (CWL2) is located in a fourth front metal layer (i.e., a fourth front conductive layer) (not shown), and is electrically connected to the word line segment (CWL1) through an interconnect element 351 that includes a front via located in a third front via layer (disposed between the fourth front metal layer and the second front metal layer 214 (see FIG. 5)) (not shown), a front landing pad located in a third front metal layer (i.e., a third front conductive layer) (disposed between the third front via layer and the second front metal layer 214 (see FIG. 5)) (not shown), and another front via located in a second front via layer (disposed between the third front metal layer and the second front metal layer 214 (see FIG. 5)) (not shown). In another example, with respect to each of the semiconductor cells 100, the word line segment (CWL2) may be located in the third front metal layer, and may be electrically connected to the word line segment (CWL1) through a front via that is located in the second front via layer. Therefore, the word lines (WL) that respectively correspond to the rows 101 can each have a low line resistance (in the X direction), and can thus cause a low RC time delay. This is beneficial to increasing the maximum operating speed of the semiconductor device.

In the cell region of each of the semiconductor cells 100, since the forth front metal layer only includes the word line segment (CWL2), the word line segment (CWL2) can be wide so as to have a low line resistance (in the X direction). Therefore, each of the word lines (WL) can have a low line resistance (in the X direction), and thus cause a low RC time delay. This is beneficial to increasing the maximum operating speed of the semiconductor device.

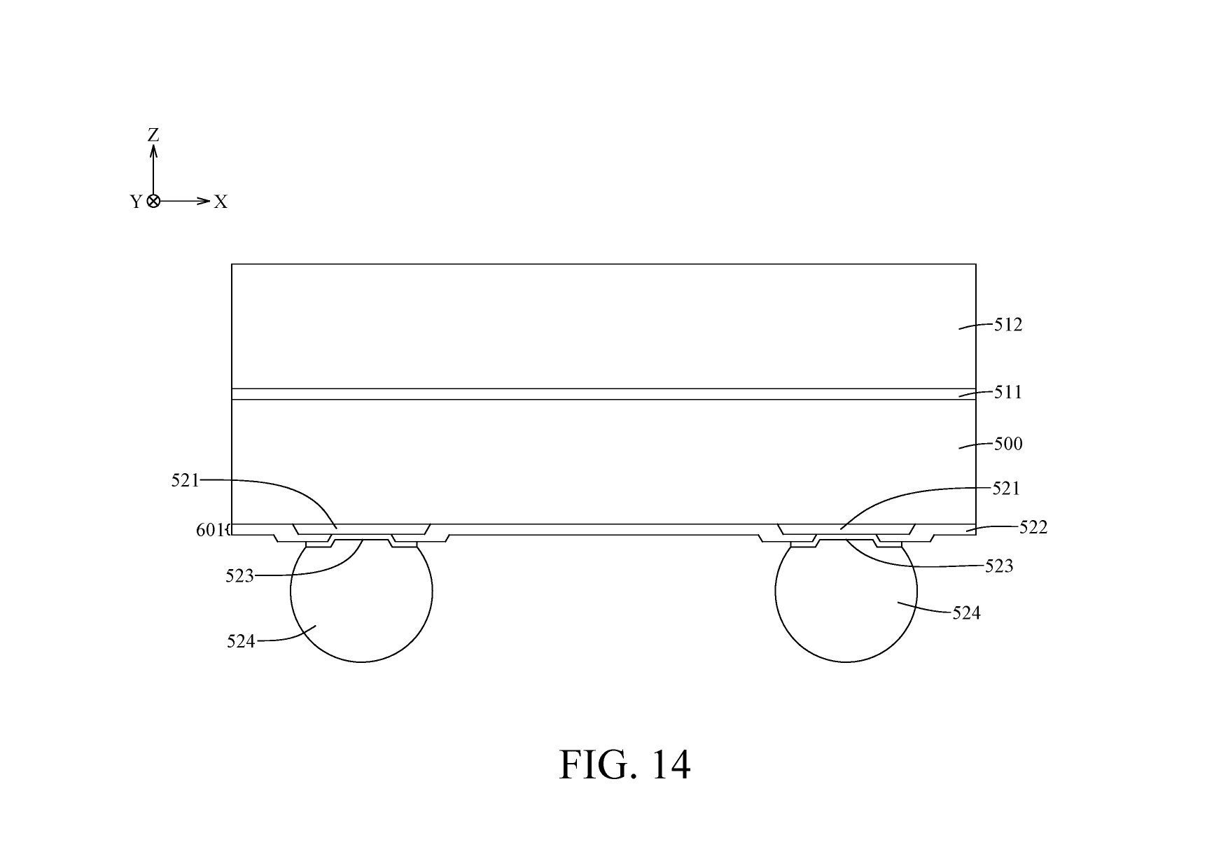

FIG. 14 is a schematic sectional view of a semiconductor device in accordance with some embodiments. Referring to FIG. 14, the semiconductor device includes a semiconductor feature 500, a dielectric layer 511, a blank substrate 512, a plurality of bump pads 521, a passivation layer 522, a plurality of under bump metallurgy (UBM) films 523 and a plurality of bump balls 524. The semiconductor feature 500 has a structure as depicted in FIGS. 1, 3 and 4. The dielectric layer 511 is disposed on an upper surface of the semiconductor feature 500. The blank substrate 512 (e.g., a silicon substrate) is disposed on an upper surface of the dielectric layer 511. The bump pads 521 are disposed on a lower surface of the semiconductor feature 500. The passivation layer 522 covers a portion of the lower surface of the semiconductor feature 500 that is not covered by the bump pads 521 and also covers an outer portion of a lower surface of each of the bump pads 521, and exposes an inner portion of the lower surface of each of the bump pads 521. Each of the UBM films 523 covers at least the inner portion of the lower surface of a respective one of the bump pads 521. Each of the bump balls 524 is disposed on a lower surface of a respective one of the UBM films 523.

Since the bump pads 521 are disposed below the semiconductor feature 500, the third VSS lines of the semiconductor feature 500 can be electrically connected to one of the bump pads 521 through an interconnect element alone, in which the interconnect element has a low resistance and causes a low voltage drop. This is beneficial to reducing the power consumption of the semiconductor device and increasing the maximum operating speed of the semiconductor device.

In some embodiments where the semiconductor feature 500 has a structure as depicted in FIGS. 1, 3 and 11, since the bump pads 521 are disposed below the semiconductor feature 500, the VDD lines of the semiconductor feature 500 can be electrically connected to one of the bump pads 521 through an interconnect element alone, in which the interconnect element has a low resistance and causes a low voltage drop. This is beneficial to reducing the power consumption of the semiconductor device and increasing the maximum operating speed of the semiconductor device.

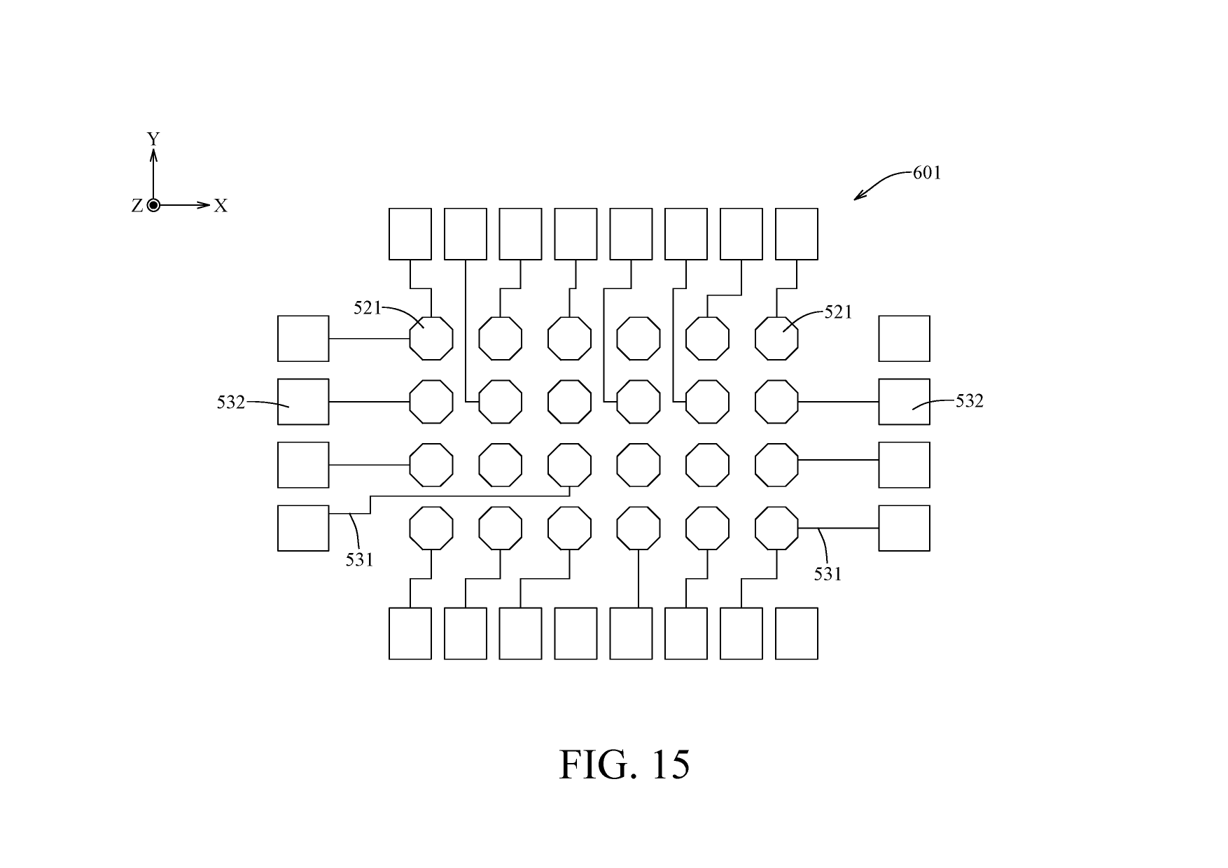

FIG. 15 is a top view of a bump pad layer in accordance with some embodiments. Referring to FIGS. 14 and 15, the bump pad layer 601 is disposed on and located below the semiconductor feature 500, and the bump pads 521 are located in the bump pad layer 601. In addition to the bump pads 521, the bump pad layer 601 may further include a plurality of metal lines 531 and a plurality of test pads 532. Each of the bump pads 521 may be electrically connected to a power line (e.g., a VDD line or a VSS line) or a signal line of the semiconductor feature 500 through an interconnect element that is disposed right above the bump pad 521, or through one of the metal lines 531 and an interconnect element that is disposed above and offset from the bump pad 521. Each of the bump pads 521 may be further electrically connected to one of the test pads 532 through one of the metal lines 531.

Referring back to FIGS. 1, 5 to 10 and 14, the semiconductor device depicted in FIGS. 1, 5 to 10 and 14 may be manufactured as described below. First, the components of the semiconductor cells 100 located in the transistor layer 200 are formed on a front side of a first substrate (not shown). Then, the components of the semiconductor cells 100 located in the layers 211-214 are formed on the transistor layer 200. Next, the dielectric layer 511 is formed on the second front metal layer 214. Then, the blank substrate 512 (i.e., a second substrate) is bonded to the dielectric layer 511. Next, the back side of the first substrate is planarized to expose the transistor layer 200. Then, the components of the semiconductor cells 100 located in the layers 221-224 are formed below the transistor layer 200. Finally, the components 521-524 are formed below the second back metal layer 224.

In accordance with some embodiments of the present disclosure, a semiconductor device includes a plurality of semiconductor cells and a front contact. The plurality of semiconductor cells are arranged in a matrix that has a plurality of rows aligned in a first direction and a plurality of columns aligned in a second direction. Each of the plurality of semiconductor cells includes a first transistor, a second transistor, a third transistor, a fourth transistor, a fifth transistor, a sixth transistor, a non-inverting bit line segment, an inverting bit line segment, a first word line segment, a first VSS line segment and a second VSS line segment. The first transistor, the second transistor, the third transistor, the fourth transistor, the fifth transistor and the sixth transistor are located in a transistor layer, and each include a gate electrode and two source/drain regions, where the first transistor, the second transistor, the third transistor and the fourth transistor cooperatively form a data latch for storing data. The non-inverting bit line segment and the inverting bit line segment are located in a first front conductive layer stacked on the transistor layer, and each extend along the first direction, where the non-inverting bit line segment is electrically connected to one of the source/drain regions of the fifth transistor, and the inverting bit line segment is electrically connected to one of the source/drain regions of the sixth transistor. The first word line segment is located in a second front conductive layer stacked on the first front conductive layer, extends along the second direction, and is electrically connected to the gate electrode of the fifth transistor and the gate electrode of the sixth transistor. The first VSS line segment and the second VSS line segment are located in a first back conductive layer stacked below the transistor layer, and each extend along the first direction, where the first VSS line segment is electrically connected to one of the source/drain regions of the third transistor, and the second VSS line segment is electrically connected to one of the source/drain regions of the fourth transistor. The front contact is located in an upper portion of the transistor layer. With respect to a first semiconductor cell and a second semiconductor cell of the plurality of semiconductor cells that are adjacent to each other in the second direction, the front contact extends from a cell region of the first semiconductor cell to a cell region of the second semiconductor cell along the second direction, and electrically connects the one of the source/drain regions of the fourth transistor of the first semiconductor cell and the one of the source/drain regions of the fourth transistor of the second semiconductor cell together.

In accordance with some embodiments of the present disclosure, with respect to each of the plurality of semiconductor cells, each of the first VSS line segment and the second VSS line segment is electrically connected to the one of the source/drain regions of a corresponding one of the third transistor and the fourth transistor through a back contact that is located in a back contact layer disposed between the transistor layer and the first back conductive layer.

In accordance with some embodiments of the present disclosure, each of the plurality of semiconductor cells further includes a first VDD line segment. The first VDD line segment is located in the first front conductive layer, extends along the first direction, and is electrically connected to one of the source/drain regions of the first transistor and one of the source/drain regions of the second transistor.

In accordance with some embodiments of the present disclosure, each of the plurality of semiconductor cells further includes a second VDD line segment. The second VDD line segment is located in the first back conductive layer, extends along the first direction, and is electrically connected to the one of the source/drain regions of the first transistor and the one of the source/drain regions of the second transistor.

In accordance with some embodiments of the present disclosure, in a cell region of each of the plurality of semiconductor cells, the second front conductive layer is free of any bit line segment, any VDD line segment and any VSS line segment.

In accordance with some embodiments of the present disclosure, each of the plurality of semiconductor cells further includes a second word line segment. The second word line segment is located in an additional front conductive layer stacked on the second front conductive layer, extends along the second direction, and is electrically connected to the first word line segment.

In accordance with some embodiments of the present disclosure, the second VSS line segment of the first semiconductor cell is in contact with the second VSS line segment of the second semiconductor cell.

In accordance with some embodiments of the present disclosure, the one of the source/drain regions of the fourth transistor of the first semiconductor cell and the one of the source/drain regions of the fourth transistor of the second semiconductor cell are electrically connected to each other through a back contact that is located in a back contact layer stacked between the transistor layer and the first back conductive layer, and that extends from the cell region of the first semiconductor cell to the cell region of the second semiconductor cell along the second direction.

In accordance with some embodiments of the present disclosure, each of the plurality of semiconductor cells further includes a third VSS line segment. The third VSS line segment is located in a second back conductive layer disposed below the first back conductive layer, extends along the second direction, and is electrically connected to the first VSS line segment and the second VSS line segment.

In accordance with some embodiments of the present disclosure, the semiconductor device further includes a plurality of bump pads. The plurality of bump pads are located in a bump pad layer that is stacked on and disposed below the first back conductive layer.

In accordance with some embodiments of the present disclosure, a semiconductor device includes a plurality of semiconductor cells and a front contact. The plurality of semiconductor cells are arranged in a matrix that has a plurality of rows aligned in a first direction and a plurality of columns aligned in a second direction. Each of the plurality of semiconductor cells includes a first transistor, a second transistor, a third transistor, a fourth transistor, a fifth transistor, a sixth transistor, a non-inverting bit line segment, an inverting bit line segment, a VDD line segment, a first word line segment, a first VSS line segment and a second VSS line segment. The first transistor, the second transistor, the third transistor, the fourth transistor, the fifth transistor and the sixth transistor are located in a transistor layer, and each include two source/drain regions. The non-inverting bit line segment, the inverting bit line segment and the VDD line segment are located in a first front conductive layer stacked on the transistor layer, and each extend along the first direction, where the VDD line segment is electrically connected to one of the source/drain regions of the first transistor and one of the source/drain regions of the second transistor. The first word line segment is located in a second front conductive layer stacked on the first front conductive layer, and extends along the second direction. The first VSS line segment and the second VSS line segment are located in a first back conductive layer stacked below the transistor layer, and each extend along the first direction, where the first VSS line segment is electrically connected to one of the source/drain regions of the third transistor, and the second VSS line segment is electrically connected to one of the source/drain regions of the fourth transistor. The front contact is located in an upper portion of the transistor layer. With respect to a first semiconductor cell and a second semiconductor cell of the plurality of semiconductor cells that are adjacent to each other in the second direction, the front contact extends from a cell region of the first semiconductor cell to a cell region of the second semiconductor cell along the second direction, and electrically connects the one of the source/drain regions of the fourth transistor of the first semiconductor cell and the one of the source/drain regions of the fourth transistor of the second semiconductor cell together.

In accordance with some embodiments of the present disclosure, in a cell region of each of the plurality of semiconductor cells, the first back conductive layer is free of any VDD line segment.

In accordance with some embodiments of the present disclosure, each of the plurality of semiconductor cells further includes a second word line segment. The second word line segment is located in an additional front conductive layer stacked on the second front conductive layer, extends along the second direction, and is electrically connected to the first word line segment. In a cell region of each of the plurality of semiconductor cells, the additional front conductive layer is free of any bit line segment, any VDD line segment and any VSS line segment.

In accordance with some embodiments of the present disclosure, each of the plurality of semiconductor cells further includes a third VSS line segment. The third VSS line segment is located in a second back conductive layer stacked below the first back conductive layer, extends along the second direction, and is electrically connected to the first VSS line segment and the second VSS line segment.

In accordance with some embodiments of the present disclosure, the one of the source/drain regions of the fourth transistor of the first semiconductor cell and the one of the source/drain regions of the fourth transistor of the second semiconductor cell are electrically connected to each other through a back contact that is located in a back contact layer disposed between the transistor layer and the first back conductive layer, and that extends from the cell region of the first semiconductor cell to the cell region of the second semiconductor cell along the second direction.

In accordance with some embodiments of the present disclosure, a semiconductor device includes a plurality of semiconductor cells and a front contact. The plurality of semiconductor cells are arranged in a matrix that has a plurality of rows aligned in a first direction and a plurality of columns aligned in a second direction. Each of the plurality of semiconductor cells includes a first transistor, a second transistor, a third transistor, a fourth transistor, a fifth transistor, a sixth transistor, a non-inverting bit line segment, an inverting bit line segment, a first word line segment, a second word line segment, a first VSS line segment and a second VSS line segment. The first transistor, the second transistor, the third transistor, the fourth transistor, the fifth transistor and the sixth transistor are located in a transistor layer, and each include two source/drain regions. The non-inverting bit line segment and the inverting bit line segment are located in a first front conductive layer stacked on the transistor layer, and each extend along the first direction. The first word line segment is located in a second front conductive layer stacked on the first front conductive layer, and extends along the second direction. The second word line segment is located in an additional front conductive layer stacked on the second front conductive layer, extends along the second direction, and is electrically connected to the first word line segment. The first VSS line segment and the second VSS line segment are located in a first back conductive layer stacked below the transistor layer, and each extend along the first direction, where the first VSS line segment is electrically connected to one of the source/drain regions of the third transistor, and the second VSS line segment is electrically connected to one of the source/drain regions of the fourth transistor. The front contact is located in an upper portion of the transistor layer. With respect to a first semiconductor cell and a second semiconductor cell of the plurality of semiconductor cells that are adjacent to each other in the second direction, the front contact extends from a cell region of the first semiconductor cell to a cell region of the second semiconductor cell along the second direction, and electrically connects the one of the source/drain regions of the fourth transistor of the first semiconductor cell and the one of the source/drain regions of the fourth transistor of the second semiconductor cell together.

In accordance with some embodiments of the present disclosure, in a cell region of each of the plurality of semiconductor cells, each of the second front conductive layer and the additional front conductive layer is free of any bit line segment, any VDD line segment and any VSS line segment.

In accordance with some embodiments of the present disclosure, the second VSS line segment of the first semiconductor cell is in contact with the second VSS line segment of the second semiconductor cell.

In accordance with some embodiments of the present disclosure, the semiconductor device further includes a plurality of bump pads. The plurality of bump pads are located in a bump pad layer that is stacked on and disposed below the first back conductive layer.

In accordance with some embodiments of the present disclosure, each of the plurality of semiconductor cells further includes a VDD line segment. The VDD line segment is located in the first front conductive layer between the non-inverting bit line segment and the inverting bit line segment, and extends along the first direction.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a plurality of semiconductor cells which are arranged in a matrix that has a plurality of rows aligned in a first direction and a plurality of columns aligned in a second direction, each of the plurality of semiconductor cells including
a first transistor, a second transistor, a third transistor, a fourth transistor, a fifth transistor and a sixth transistor which are located in a transistor layer, and each of which includes a gate electrode and two source/drain regions, where the first transistor, the second transistor, the third transistor and the fourth transistor cooperatively form a data latch for storing data,
a non-inverting bit line segment and an inverting bit line segment which are located in a first front conductive layer stacked on the transistor layer, and each of which extends along the first direction, where the non-inverting bit line segment is electrically connected to one of the source/drain regions of the fifth transistor, and the inverting bit line segment is electrically connected to one of the source/drain regions of the sixth transistor,
a first word line segment which is located in a second front conductive layer stacked on the first front conductive layer, extends along the second direction, and is electrically connected to the gate electrode of the fifth transistor and the gate electrode of the sixth transistor, and
a first VSS line segment and a second VSS line segment which are located in a first back conductive layer stacked below the transistor layer, and each of which extends along the first direction, where the first VSS line segment is electrically connected to one of the source/drain regions of the third transistor, and the second VSS line segment is electrically connected to one of the source/drain regions of the fourth transistor; and
a front contact located in an upper portion of the transistor layer;
with respect to a first semiconductor cell and a second semiconductor cell of the plurality of semiconductor cells that are adjacent to each other in the second direction, the front contact extending from a cell region of the first semiconductor cell to a cell region of the second semiconductor cell along the second direction, and electrically connecting the one of the source/drain regions of the fourth transistor of the first semiconductor cell and the one of the source/drain regions of the fourth transistor of the second semiconductor cell together.

2. The semiconductor device according to claim 1, wherein:
with respect to each of the plurality of semiconductor cells, each of the first VSS line segment and the second VSS line segment is electrically connected to the one of the source/drain regions of a corresponding one of the third transistor and the fourth transistor through a back contact that is located in a back contact layer disposed between the transistor layer and the first back conductive layer.

3. The semiconductor device according to claim 1, wherein each of the plurality of semiconductor cells further includes:
a first VDD line segment located in the first front conductive layer, extending along the first direction, and electrically connected to one of the source/drain regions of the first transistor and one of the source/drain regions of the second transistor.

4. The semiconductor device according to claim 3, wherein each of the plurality of semiconductor cells further includes:
a second VDD line segment located in the first back conductive layer, extending along the first direction, and electrically connected to the one of the source/drain regions of the first transistor and the one of the source/drain regions of the second transistor.

5. The semiconductor device according to claim 1, wherein:
in a cell region of each of the plurality of semiconductor cells, the second front conductive layer is free of any bit line segment, any VDD line segment and any VSS line segment.

6. The semiconductor device according to claim 1, wherein each of the plurality of semiconductor cells further includes:
a second word line segment located in an additional front conductive layer that is stacked on the second front conductive layer, extending along the second direction, and electrically connected to the first word line segment.

7. The semiconductor device according to claim 1, wherein:
the second VSS line segment of the first semiconductor cell is in contact with the second VSS line segment of the second semiconductor cell.

8. The semiconductor device according to claim 1, wherein:
the one of the source/drain regions of the fourth transistor of the first semiconductor cell and the one of the source/drain regions of the fourth transistor of the second semiconductor cell are electrically connected to each other through a back contact that is located in a back contact layer stacked between the transistor layer and the first back conductive layer, and that extends from the cell region of the first semiconductor cell to the cell region of the second semiconductor cell along the second direction.

9. The semiconductor device according to claim 1, wherein each of the plurality of semiconductor cells further includes:
a third VSS line segment located in a second back conductive layer that is disposed below the first back conductive layer, extending along the second direction, and electrically connected to the first VSS line segment and the second VSS line segment.

10. The semiconductor device according to claim 1, further comprising:
a plurality of bump pads located in a bump pad layer that is stacked on and disposed below the first back conductive layer.

11. A semiconductor device comprising:
a plurality of semiconductor cells which are arranged in a matrix that has a plurality of rows aligned in a first direction and a plurality of columns aligned in a second direction, each of the plurality of semiconductor cells including
a first transistor, a second transistor, a third transistor, a fourth transistor, a fifth transistor and a sixth transistor which are located in a transistor layer, and each of which includes two source/drain regions,
a non-inverting bit line segment, an inverting bit line segment and a VDD line segment which are located in a first front conductive layer stacked on the transistor layer, and each of which extends along the first direction, where the VDD line segment is electrically connected to one of the source/drain regions of the first transistor and one of the source/drain regions of the second transistor,
a first word line segment which is located in a second front conductive layer stacked on the first front conductive layer, and extends along the second direction, and
a first VSS line segment and a second VSS line segment which are located in a first back conductive layer stacked below the transistor layer, and each of which extends along the first direction, where the first VSS line segment is electrically connected to one of the source/drain regions of the third transistor, and the second VSS line segment is electrically connected to one of the source/drain regions of the fourth transistor; and
a front contact located in an upper portion of the transistor layer;
with respect to a first semiconductor cell and a second semiconductor cell of the plurality of semiconductor cells that are adjacent to each other in the second direction, the front contact extending from a cell region of the first semiconductor cell to a cell region of the second semiconductor cell along the second direction, and electrically connecting the one of the source/drain regions of the fourth transistor of the first semiconductor cell and the one of the source/drain regions of the fourth transistor of the second semiconductor cell together.

12. The semiconductor device according to claim 11, wherein:
in a cell region of each of the plurality of semiconductor cells, the first back conductive layer is free of any VDD line segment.

13. The semiconductor device according to claim 11, wherein each of the plurality of semiconductor cells further includes:
a second word line segment located in an additional front conductive layer that is stacked on the second front conductive layer, extending along the second direction, and electrically connected to the first word line segment; and
in a cell region of each of the plurality of semiconductor cells, the additional front conductive layer is free of any bit line segment, any VDD line segment and any VSS line segment.

14. The semiconductor device according to claim 11, wherein each of the plurality of semiconductor cells further includes:
a third VSS line segment located in a second back conductive layer that is stacked below the first back conductive layer, extending along the second direction, and electrically connected to the first VSS line segment and the second VSS line segment.

15. The semiconductor device according to claim 11, wherein:
the one of the source/drain regions of the fourth transistor of the first semiconductor cell and the one of the source/drain regions of the fourth transistor of the second semiconductor cell are electrically connected to each other through a back contact that is located in a back contact layer disposed between the transistor layer and the first back conductive layer, and that extends from the cell region of the first semiconductor cell to the cell region of the second semiconductor cell along the second direction.

16. A semiconductor device comprising:
a plurality of semiconductor cells which are arranged in a matrix that has a plurality of rows aligned in a first direction and a plurality of columns aligned in a second direction, each of the plurality of semiconductor cells including
a first transistor, a second transistor, a third transistor, a fourth transistor, a fifth transistor and a sixth transistor which are located in a transistor layer, and each of which includes two source/drain regions,
a non-inverting bit line segment and an inverting bit line segment which are located in a first front conductive layer stacked on the transistor layer, and each of which extends along the first direction,
a first word line segment which is located in a second front conductive layer stacked on the first front conductive layer, and extends along the second direction,
a second word line segment which is located in an additional front conductive layer stacked on the second front conductive layer, extends along the second direction, and is electrically connected to the first word line segment, and
a first VSS line segment and a second VSS line segment which are located in a first back conductive layer stacked below the transistor layer, and each of which extends along the first direction, where the first VSS line segment is electrically connected to one of the source/drain regions of the third transistor, and the second VSS line segment is electrically connected to one of the source/drain regions of the fourth transistor; and
a front contact located in an upper portion of the transistor layer;
with respect to a first semiconductor cell and a second semiconductor cell of the plurality of semiconductor cells that are adjacent to each other in the second direction, the front contact extending from a cell region of the first semiconductor cell to a cell region of the second semiconductor cell along the second direction, and electrically connecting the one of the source/drain regions of the fourth transistor of the first semiconductor cell and the one of the source/drain regions of the fourth transistor of the second semiconductor cell together.

17. The semiconductor device according to claim 16, wherein:
in a cell region of each of the plurality of semiconductor cells, each of the second front conductive layer and the additional front conductive layer is free of any bit line segment, any VDD line segment and any VSS line segment.

18. The semiconductor device according to claim 16, wherein:
the second VSS line segment of the first semiconductor cell is in contact with the second VSS line segment of the second semiconductor cell.

19. The semiconductor device according to claim 16, further comprising:
a plurality of bump pads located in a bump pad layer that is stacked on and disposed below the first back conductive layer.

20. The semiconductor device according to claim 16, wherein each of the plurality of semiconductor cells further includes:
a VDD line segment located in the first front conductive layer between the non-inverting bit line segment and the inverting bit line segment, and extending along the first direction.
